(19) United States
(12) Patent Application Publication
(10) Pub. No.: US 2009/0205699 A1
(43) Pub. Date: Aug. 20, 2009

(54) Solar-power collector

(76) Inventor: Kuo-Wen Chang, Taichung (TW)

Correspondence Address: GENIUS ELECTRONIC OPTICAL CO., LTD, P.O. BOX 215, TAICHUNG, 40099, TW

(21) Appl. No.: 12/155,405

(22) Filed: Jun. 4, 2008

(30) Foreign Application Priority Data
Feb. 15, 2008 (TW) 097202808

(51) Int. Cl. H01L 31/052

(52) U.S. Cl. 136/246

(57) ABSTRACT

This invention proposes one kind of solar-power collecting apparatus that utilizes different lens structure and double layers of solar panel modules to optimize the absorption of solar power within a limited space, and better protect the life of solar panels by avoiding overheats generated from overly focused sunlight.

### BACKGROUND OF THE INVENTION

This invention is regarding to a technique that can optimize the absorption of solar power within a limited space, and prolong the life of solar panels.

Current solar power collecting techniques generally come from two methods by principles: (1) utilize and achieve through heat chamber. (2) utilize reflection mirrors or lens to focus sunlight on the surfaces of solar panels for them to absorb. Aforementioned two methods can both achieve to turn solar power into electricity, but they require big space and dimension to collect sufficient solar power. Unfortunately, the bigger size the apparatus is, the costly it will be. In Taiwan Patent Publication Number: M3 18670 “Refraction-based solar power collector”, for example, it comprises: a light-directing device, a transparent body with continuous pyramid-structured, a reflective device used to reflect the light refracted from the light-directing device and a solar panel. The light-directing device, reflective device and the solar panel form into a cube with the solar panel at bottom, the light-directing device between the light source and the solar panel, and the reflective device between the light-directing device and the solar panel. The light-directing device first refracts the light onto the reflective device, and then light will be reflected onto the solar panel for collecting solar power.

Although the light-directing and reflective devices can greatly have sunlight focused on the solar panel, it indeed also has following drawbacks: (1) Although the its solar panels are properly spaced to save manufacturing costs, it encounters the loss of some sunlight and may at some certain times fail to direct lights focused onto the solar panel due to the displacement of sunlight, thus causing low collecting efficiency. (2) Like other regular solar-power collectors, such equipment also requires the wide placement of solar panels when in condition of unable to fully absorb sunlight, causing high implementing costs and thus hard to get popular. (3) In real practice, the focused sunlight from the light-directing devices ever burned the solar panel. Thus, with long time investments in researches and experiments, the inventor finally found an improved structure that can prevent aforementioned problems, and thus hereby proudly files application of patent to protect intellectual property.

### BRIEF SUMMARY OF THE INVENTION

This invention proposes a solar-power collector that can double collect solar power under same total solar panel size as traditional apparatus. Accordingly, it can generate sufficient electrical power without requiring solar panel of big dimension, can be produced at lower unit cost, can be spread out more easily to regular households, and it has also the feature of long life.

To reach the abovementioned ends, the invention proposes a solar-power collector, which comprises:

A transparent light deflector—composed of stacks of transparent plates, it has multiple convexes and concaves on either its top of bottom surface. The convexes can be either round-shaped, cone-shaped, pyramid-, awl-shaped, or trapezoid column-shaped, and their arrangement can be in either crisscross or random alignments;

Two or more layers of solar panel modules—they are placed beneath the light deflector. Each solar panel module is composed of multiple solar panels that scatter around, and the solar panels of upper and lower layers are intercross placed. With so, sunlight can focus and disperse through the convexes and concaves of the light deflector, and the upper layer of solar panel module absorbs the dispersed sunlight while the lower layer module, through the gaps between panels of upper layer module, absorbs the after-focus dispersed sunlight. This is designed so to fully absorb sunlight and avoid overheating problem when sunlight just focuses on certain points on solar panels.

### BRIEF DESCRIPTION OF THE DRAWINGS

FIG. 1—an exploded view of first preferred embodiment

FIG. 2—a sectional view of first preferred embodiment in assembly

FIG. 3—a perspective view of second preferred embodiment for light deflector

FIG. 4—a perspective view of third preferred embodiment for light deflector

FIG. 5—a perspective view of fourth preferred embodiment for light deflector

FIG. 6—a sectional view of FIG. 5 in assembly with solar panels

FIG. 7—a perspective view of fifth preferred embodiment for light deflector

FIG. 8—a perspective view of sixth preferred embodiment for light deflector

### DETAILED DESCRIPTION OF THE INVENTION

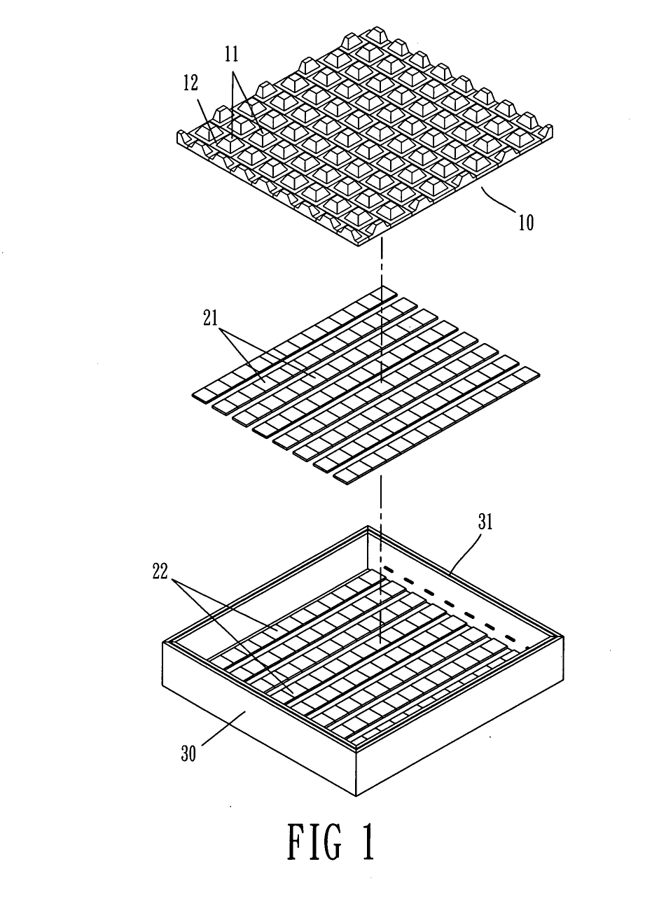

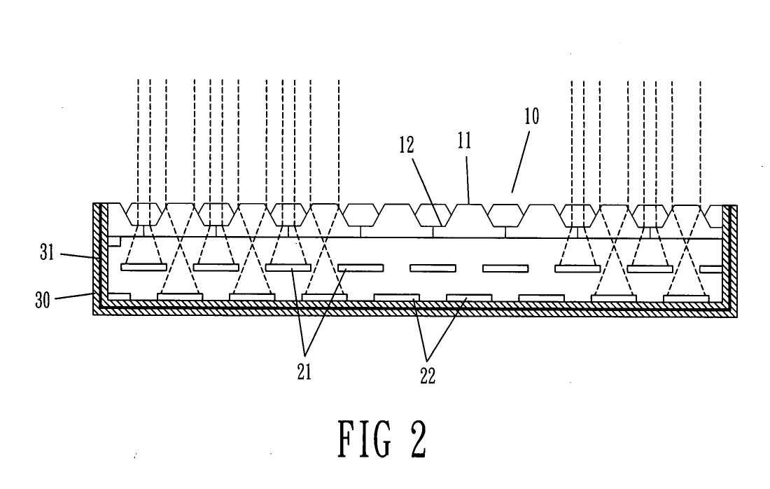

Further, please be described of a preferred embodiment as below. First referring to FIG. 1 and 2, the invention comprises: a transparent light deflector 10, and at least upper and lower layers of solar panel modules 21, 22 below the light deflector 10.

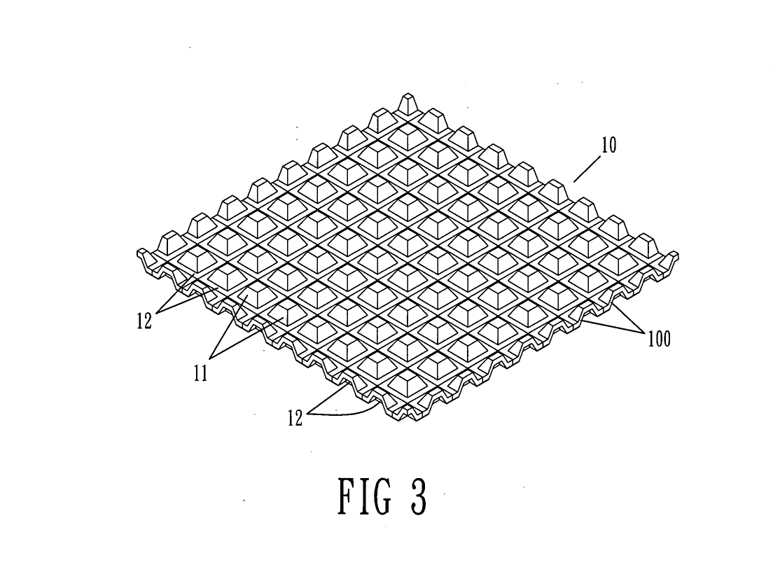

The transparent light deflector 10 has multiple convexes 11 and concaves 12 on either its top of bottom surface. The convexes 11 can be either round-shaped, cone-shaped, pyramid-, awl-shaped, or trapezoid column-shaped. The concaves 12 can be not only on top surface but also on bottom surface at the corresponding positions to the convexes 11 as shown in FIG. 3. The arrangement of the convexes 11 can be in either 2-D crisscross or random alignments, thus looks continuous or intercross wave-shape, triangle-shape or trapezoid-shape in its sectional view.

The two layers of solar panel modules 21, 22 placed beneath the light deflector. Each solar panel module is composed of multiple solar panels in 2-D alignments, and the solar panels of the two modules are placed in an intercross format. With so, sunlight can focus and disperse through the convexes 11 and concaves 12 of the light deflector 10, and the upper solar panel module 21 absorbs the dispersed sunlight while the lower module 22, through the gaps between solar panels of upper module 21, absorbs the after-focus dispersed sunlight. This is designed so to effectively and fully absorb sunlight power and avoid overheating problem when sunlight just focuses on certain points on solar panels.

For supplements, the gap between the solar panels of upper solar panel module 21 cannot be too small, because too small gap may cause over-concentration of solar power, which may burn down the solar panels. Thus, the design of convexes 11 should be so that the solar panels can bear the temperature of the solar power coming through the convexes 11.

Further, the invention also comprises a containing body 30 used to contain and position light deflector 10, upper solar panel module 21 and lower solar panel module 22. The containing body 30 can be so that inside its four side and bottom plates set heat-insulation layers 31, and inner walls of them get coated with reflection layers.

Furthermore, this invention can be also implemented as below examples. As shown in FIG. 3, the light deflector 10 is composed of multiple lens units 100, each of which contains of a convex part 11 and its corresponding concave part 12. The convex parts 11 are trapezoid column-shaped and in 2-D crisscross alignment, and they are capable of making sun light disperse-after-focus. The light deflector looks continuous trapezoid-shaped in its sectional view.

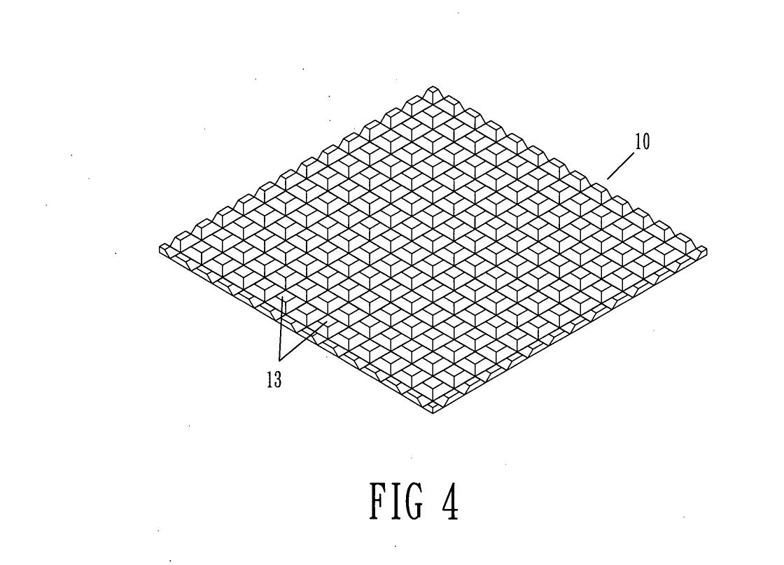

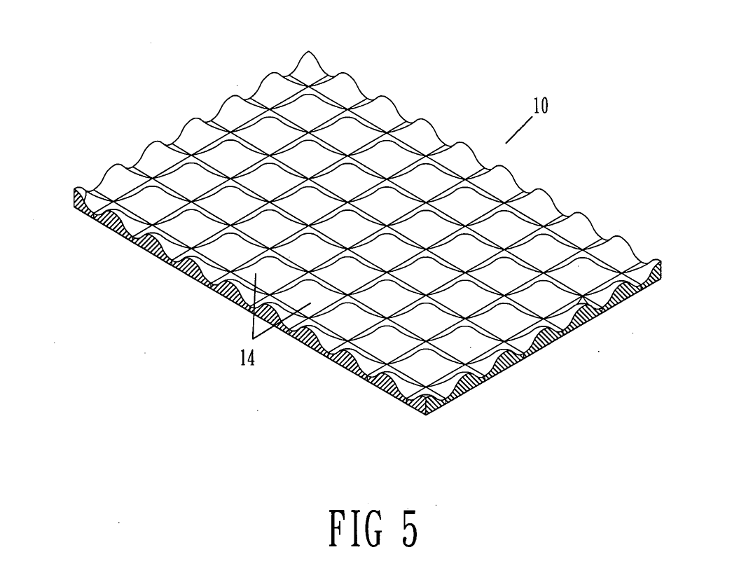

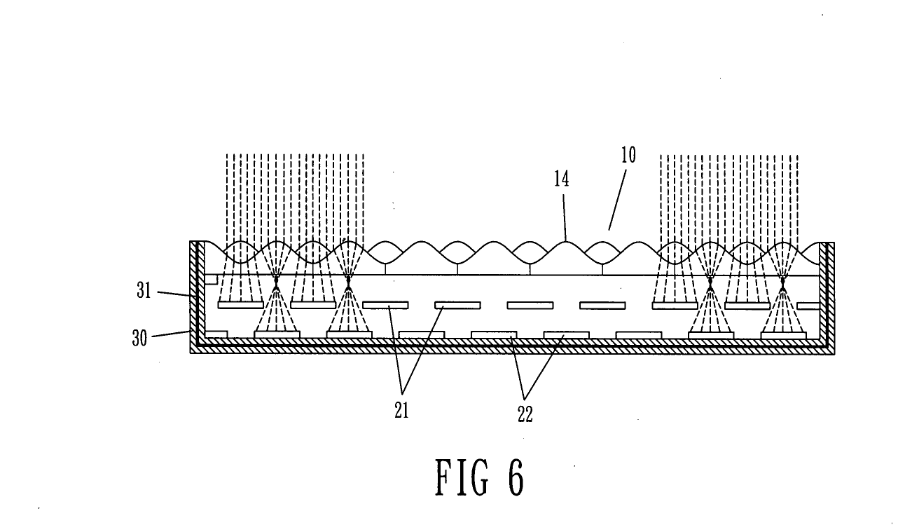

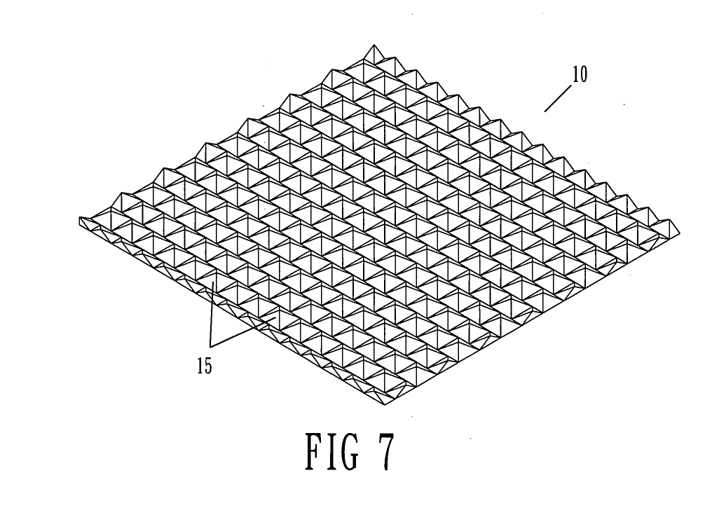

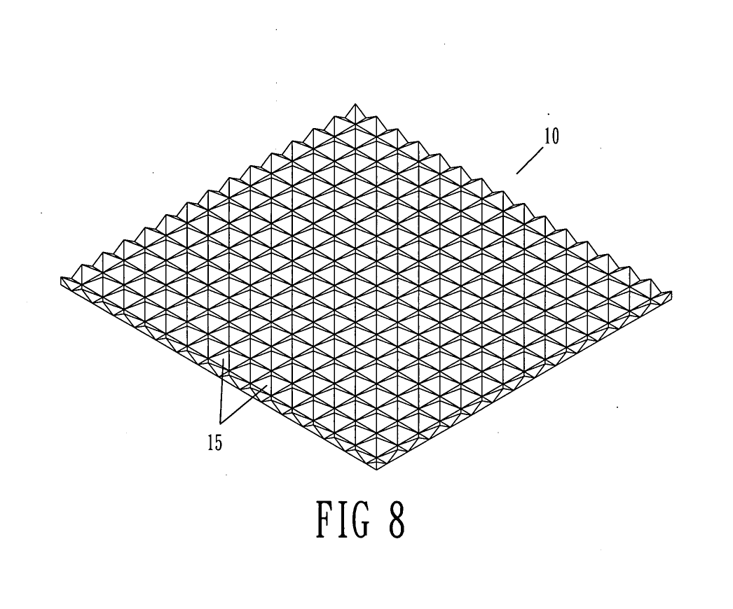

As shown in FIG. 4, the light deflector 10 is composed of multiple trapezoid column-shaped lens 13, and looks continuous trapezoid-shaped in its sectional view. And as shown in FIG. 5 and 6, the light deflector 10 is composed of multiple round-shaped lens units 14 so that it perform as convex and concave lens, and it looks wave-shaped in its sectional view. Further as shown in FIGS. 7 and 8, the light deflector 10 is composed of multiple pyramid-shaped lens units 15 that are in either 2-D crisscross or interlace alignment, and it looks continuous or intercross triangle-shaped in its sectional view.

With all aforementioned, the invention deserves grant of a patent based on its capability of industrial application and absolute novelty. The example illustrated above is just an exemplary embodiment for the invention, and shall not be utilized to confine the scope of the patent. Any equivalent modifications within the scope of claims of the patent shall be covered in the protection for this patent.

What is claimed is:

1. A solar-power collector that comprises: a light deflector that has multiple convexes and concaves on either its top of bottom surface, and two or more layers of solar panel modules placed beneath the light deflector, each of them is composed of multiple solar panels that are scatter aligned.

2. The solar-power collector of claim 1, wherein the said light deflector is composed of stacks of transparent plates.

3. The solar-power collector of claim 2, wherein the said transparent plates has at least a convex or concave on its top or bottom surface.

4. The solar-power collector of claim 1, wherein the said convexes of the said light deflector can be round-shaped, cone-shaped, pyramid-shaped, awl-shaped, or trapezoid column-shaped.

5. The solar-power collector of claim 1, wherein the said convexes of the said light deflector are either in 2-D crisscross, interlace, or random alignment.

6. The solar-power collector of claim 1, wherein the said light deflector looks continuous or intercross wave-shaped in its sectional view.

7. The solar-power collector of claim 1, wherein the said light deflector looks continuous or intercross triangle-shaped in its sectional view.

8. The solar-power collector of claim 1, wherein the said light deflector looks continuous or intercross trapezoid -shaped in its sectional view.
